(19) United States
(12) Patent Application Publication
(10) Pub. No.: US 2004/0061197 A1
(43) Pub. Date: Apr. 1, 2004

(54) Method and apparatus to fabricate an on-chip decoupling capacitor

(75) Inventors: Bruce Block, Portland, OR (US); Christopher Thomas, Aloha, OR (US)

Correspondence Address: Pillsbury Winthrop LLP, Intellectual Property Group, Suite 2800, 725 South Figueroa Street, Los Angeles, CA, 90017-5406, US

(73) Assignee: Intel Corporation, Santa Clara, CA

(21) Appl. No.: 10/261,225

(22) Filed: Sep. 30, 2002

(51) Int. Cl. H01L 29/00

(52) U.S. Cl. 257/532

(57) ABSTRACT

A method of fabricating a decoupling capacitor includes depositing a first barrier metal on a conducting metal. The first barrier metal acts as a first electrode of the decoupling capacitor. A dielectric is deposited on the first barrier metal. A second barrier metal is deposited on the dielectric. The second barrier metal acts as a second electrode of the decoupling capacitor. A photoresist is exposed to ultraviolet light. The photoresist is applied on the second barrier metal. A mask is utilized to define an approximate shape of the decoupling capacitor. A portion of the second barrier metal is etched. A quantity of the photoresist is removed.

### BACKGROUND

1. Technical Field

An embodiment of the present invention generally relates to a capacitor. More particularly, an embodiment of the present invention relates to an on-chip decoupling capacitor.

2. Discussion of the Related Art

A decoupling capacitor is often implemented in a semiconductor chip to reduce noise, such as current spikes, that may interfere with optimum operation of the semiconductor chip. The decoupling capacitor has traditionally been implemented by inserting a capacitor structure between metalization layers in a backend process. An etch operation is often performed on the capacitor structure to remove any excess metal that was used to create the top electrode of the capacitor. This scheme generally exposes an underlying conducting metal, such as copper, to an etch chemistry. Exposing the conducting metal to the etch chemistry may severely compromise the conducting properties of the conducting metal. For example, copper is a reactive material, which reacts with a sulfur hexafluoride/argon (“SF₆/Ar”) etch chemistry, the preferred etch chemistry for a barrier electrode etch. Thus, if copper is exposed to the etch chemistry, the copper may be rendered less effective as a conductor.

Moreover, an oxygen plasma ash operation is generally performed to remove photoresist from the capacitor structure. As with the etch operation, the oxygen plasma ash operation is performed while the conducting metal is not exposed. Otherwise, the oxygen plasma ash operation may result in oxidation of the conducting metal. The etch operation of the capacitor structure typically requires additional operations to protect against exposing the conducting metal during the oxygen plasma ash operation, and these additional operations have a negative impact on high volume manufacturing of the semiconductor chip. Due to the risk of exposing the conducting metal, the etch operation typically does not remove all of the excess metal that is used to create the top electrode of the capacitor. Thus, a second etch operation is generally performed with the SF₆/Ar etch chemistry to etch through a remainder of the excess metal that is used to create the top electrode of the capacitor, a dielectric, and a majority of the excess metal that is used to create the bottom electrode of the capacitor. The etch chemistry is typically changed to methyl difluoride (“CH₂F₂”) because it is not likely to corrode the conducting metal. However, an etch rate of the bottom electrode of the capacitor is generally slow as compared to the etch rate of an interlayer dielectric (“ILD”), which typically exists beneath the conducting metal. Thus, any over-etch used to account for non-uniformity may severely etch the ILD.

### BRIEF DESCRIPTION OF THE DRAWINGS

FIG. 1 illustrates a flow chart for a method of fabricating a decoupling capacitor according to an embodiment of the present invention;

FIG. 2a illustrates a cross section of a semiconductor chip after a first barrier metal has been deposited according to an embodiment of the present invention;

FIG. 2b illustrates a cross section of a semiconductor chip after a dielectric has been deposited according to an embodiment of the present invention;

FIG. 2c illustrates a cross section of a semiconductor chip after a second barrier metal has been deposited according to an embodiment of the present invention;

FIG. 2d illustrates a cross section of a semiconductor chip showing a photoresist being exposed to ultraviolet light according to an embodiment of the present invention;

FIG. 2e illustrates a cross section of a semiconductor chip after a portion of the second barrier metal has been etched according to an embodiment of the present invention;

FIG. 2f illustrates a cross section of a semiconductor chip after a quantity of photoresist has been removed according to an embodiment of the present invention;

FIG. 3 illustrates a cross section of a semiconductor chip that incorporates a decoupling capacitor according to an embodiment of the present invention; and

FIG. 4 illustrates a block diagram of a semiconductor chip that incorporates a decoupling capacitor according to an embodiment of the present invention.

### DETAILED DESCRIPTION

Reference in the specification to “one embodiment”, “an embodiment”, or “another embodiment” of the present invention means that a particular feature, structure or characteristic described in connection with the embodiment is included in at least one embodiment of the present invention. Thus, the appearances of the phrase “in one embodiment” or “according to an embodiment” appearing in various places throughout the specification are not necessarily all referring to the same embodiment. Likewise, appearances of the phrase “in another embodiment” or “according to another embodiment” appearing in various places throughout the specification are not necessarily referring to different embodiments.

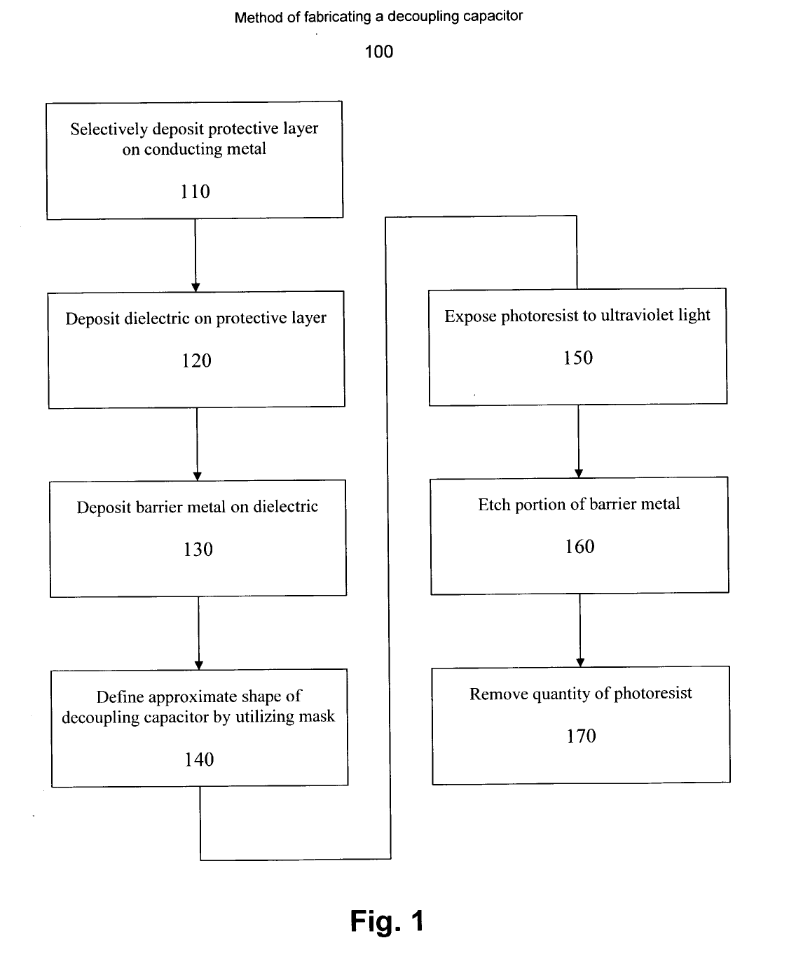

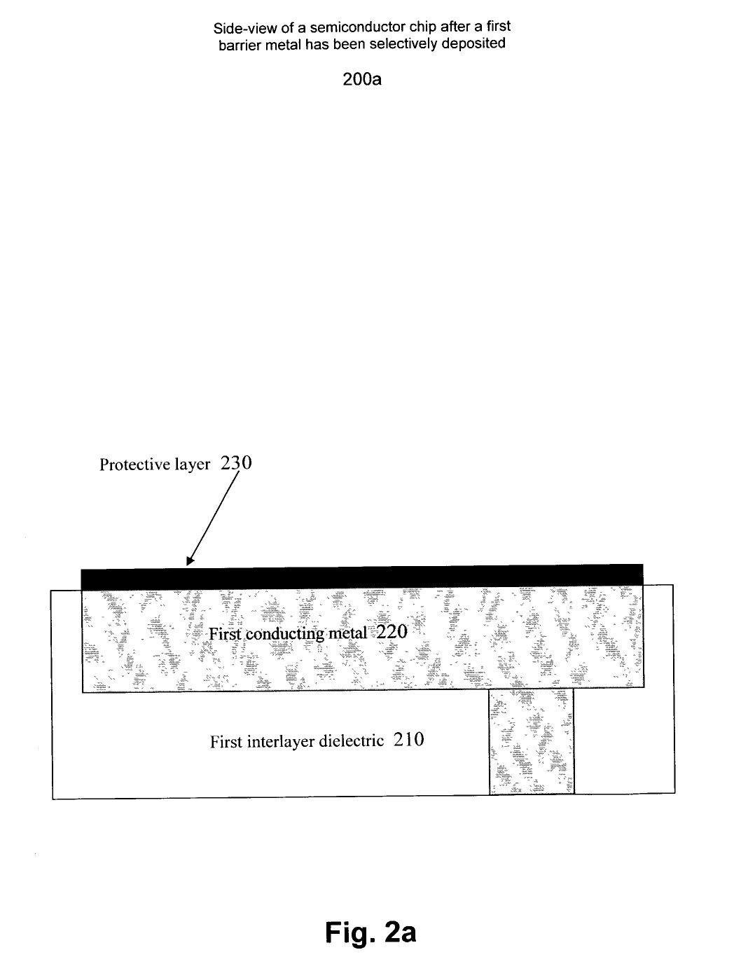

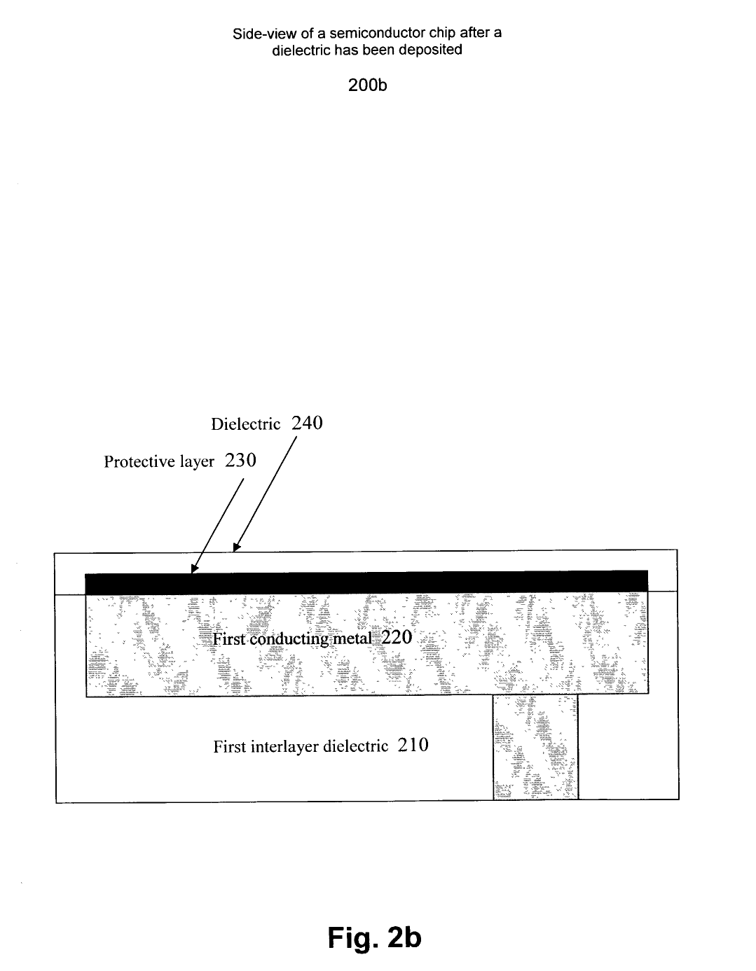

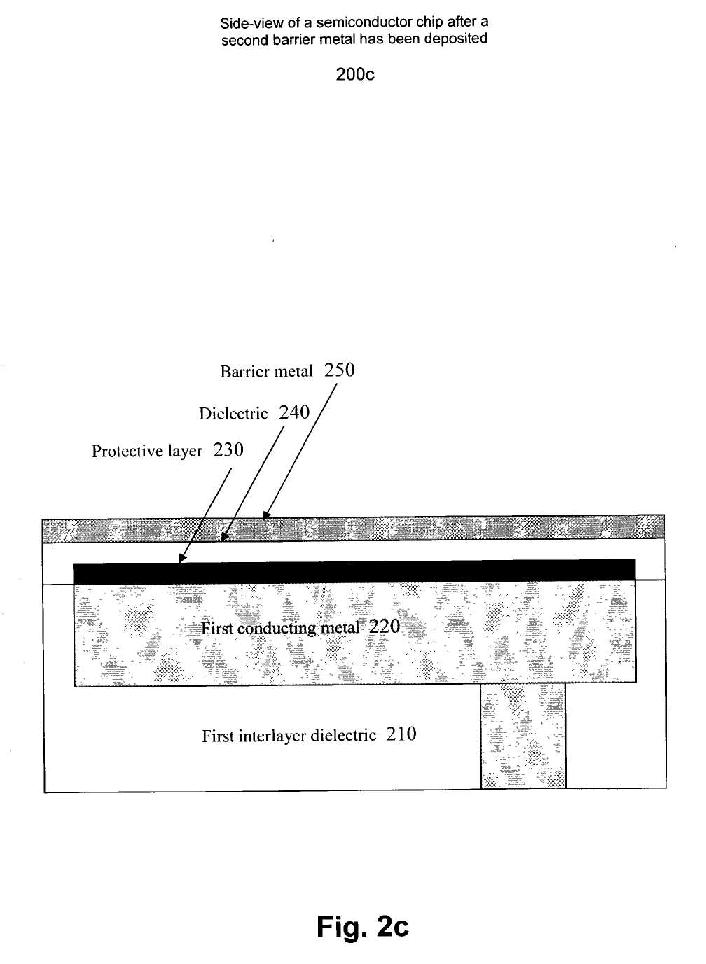

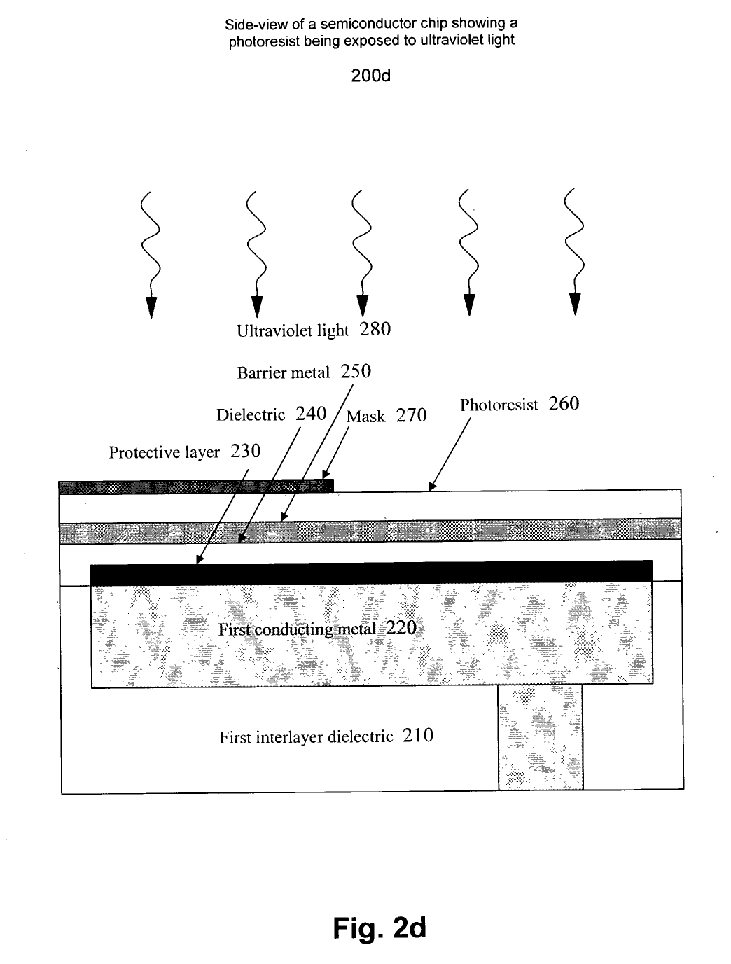

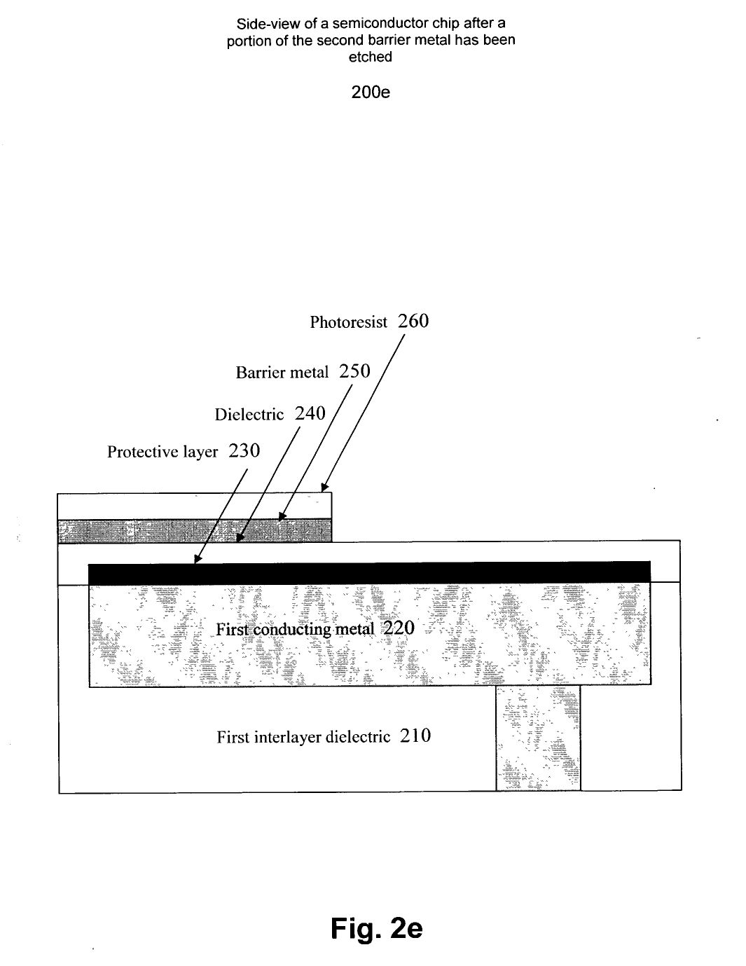

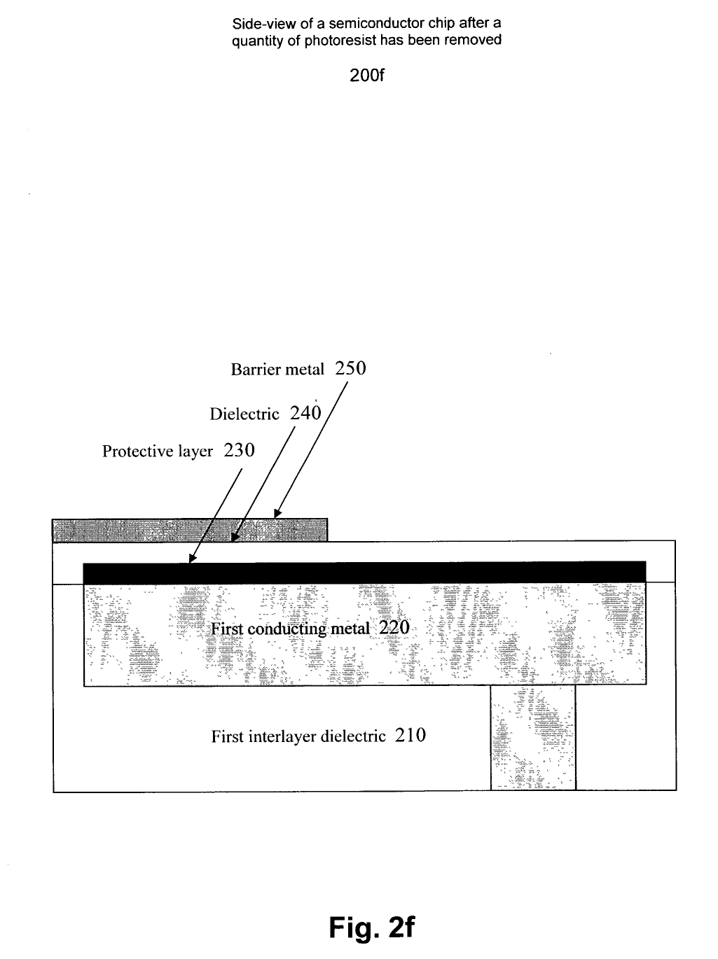

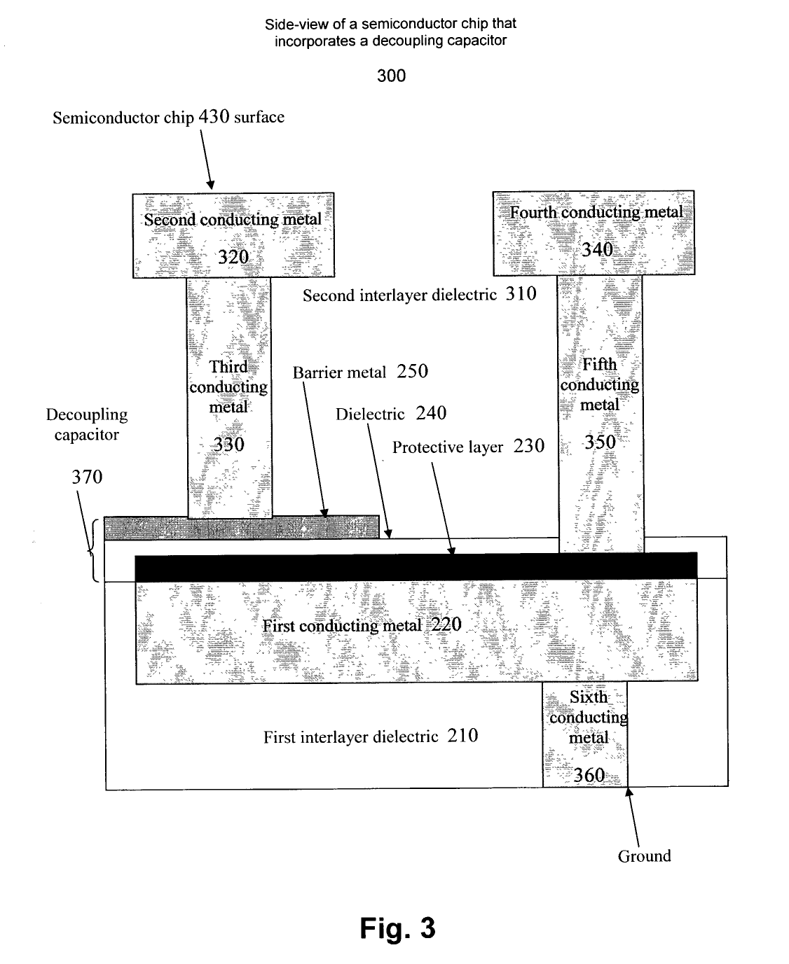

FIG. 1 illustrates a flow chart for a method of fabricating a decoupling capacitor according to an embodiment of the present invention. Within the method and referring to FIG. 1, FIGS. 2a-2f, and FIG. 3, a first conducting metal 220 may be deposited on a first interlayer dielectric 210. A protective layer 230 (see FIG. 2a) is selectively deposited 110 on the first conducting metal 220, which means that the protective layer 230 is deposited entirely on the first conducting metal 220, rather than on the first interlayer dielectric 210. The protective layer 230 acts as a first electrode of the decoupling capacitor 370 (see FIG. 3). The protective layer 230 may further act as an oxygen barrier to the first conducting metal 220. The protective layer 230 may further act as an etch stop layer, for example, eliminating the need for a conventional etch stop layer for a via etch. The protective layer 230 may further act as an etch barrier to the first conducting metal 220, for example, during a decap etch process. The protective layer 230 may reduce electrical shorting due to etch stringers and may provide a less costly solution than a conventional patterned first electrode. A dielectric 240 (see FIG. 2b) is deposited 120 on the protective layer 230. The protective layer 230 may further act as a diffusion barrier of the first conducting metal 220 to the dielectric 240. A barrier metal 250 (see FIG. 2c) is deposited 130 on the dielectric 240. The barrier metal 250 acts as a second electrode of the decoupling capacitor 370 (see FIG. 3). The dielectric 240 may have a high dielectric constant, which enables the first electrode and the second electrode of the decoupling capacitor 370 to hold more charge and/or to hold charge for a longer period of time, as compared to a decoupling capacitor that includes a dielectric having a lower dielectric constant. The protective layer 230 and/or the barrier metal 250 may be a refractory metal, which is stable up to a very high temperature. For example, a backend process may expose the decoupling capacitor 370 to a temperature of 450° C., in which environment a refractory metal may remain stable. In addition, refractory metals generally have low diffusion constants, making them good barriers to copper diffusion, which may contaminate the dielectric 240. A photoresist 260 is applied on the barrier metal 250. An appropriate shape of the decoupling capacitor 370 is defined 140 by utilizing a mask 270 (see FIG. 2d). The photoresist 260 (see FIG. 2d) is exposed 150 to ultravoilet light 280. A portion of the barrier metal 250 (see FIG. 2e) is etched 160. A quantity of the photoresist 260 (see FIG. 2f) is removed 170. A quantity of the photoresist 260 may be defined to mean all of the photoresist 260.

According to an embodiment of the present invention, the protective layer 230 may include cobalt (“Co”). In an embodiment, the protective layer 230 may include tungsten (“W”). The tungsten may be applied by chemical vapor deposition (“CVD”); however, any suitable method may be used. In one embodiment, the first conducting metal 220 may include copper (“Cu”). The barrier metal 250 may include tantalum (“Ta”). For example, the barrier metal 250 may be tantalum nitride (“TaN”) or merely tantalum. In another embodiment, the barrier metal 250 may include titanium (“Ti”). For example, the barrier metal 250 may be titanium nitride (TiN”). According to yet another embodiment, removing 170 the quantity of the photoresist 260 may be performed by an oxygen (“O₂”) plasma ash operation. The dielectric 240 may have a high dielectric constant.

FIGS. 2a-2f illustrate a cross section of a semiconductor chip at various points during fabrication process according to an embodiment of the present invention. FIG. 2a illustrates the cross section of the semiconductor chip after a protective layer 230 has been selectively deposited according to an embodiment of the present invention. FIG. 2b illustrates the cross section of the semiconductor chip after a dielectric 240 has been deposited according to an embodiment of the present invention. FIG. 2c illustrates the cross section of the semiconductor chip after a barrier metal 250 has been deposited according to an embodiment of the present invention. FIG. 2d illustrates the cross section of the semiconductor chip showing a photoresist 260 being exposed to ultraviolet light according to an embodiment of the present invention. When the photoresist 260 is exposed, not all of the photoresist 260 need be exposed. A mask 270 may block a portion of the photoresist 260 from being exposed to the ultraviolet light 280. FIG. 2e illustrates the cross section of the semiconductor chip after a portion of the barrier metal 250 has been etched according to an embodiment of the present invention. A portion of the photoresist 260 may be removed when the barrier metal 250 is etched. For a positive photoresist, a portion of the photoresist 260 that was exposed to the ultraviolet light 280 may be removed. For a negative photoresist, the portion of the photoresist 260 that was blocked by the mask 270 may be removed. FIG. 2f illustrates the cross section of the semiconductor chip after a quantity of photoresist has been removed according to an embodiment of the present invention. The quantity of the photoresist 260 that is removed is at least a part of the portion of the photoresist 260 that was not removed when the barrier metal 250 was etched.

FIG. 3 illustrates a cross section of a semiconductor chip that incorporates a decoupling capacitor according to an embodiment of the present invention. The decoupling capacitor 370 includes a protective layer 230, a dielectric 240, and a barrier metal 250. The protective layer 230 is selectively deposited on a first conducting metal 220. The protective layer 230 acts as a first electrode of the decoupling capacitor 370. The protective layer 230 may be conductive. The dielectric 240 is connected to the protective layer 230. The barrier metal 250 is connected to the dielectric 240 and to a second conducting metal 320. The barrier metal 250 acts as a second electrode of the decoupling capacitor 370.

According to an embodiment of the present invention, the second conducting metal 320 may include copper (“Cu”). The first conducting metal 220 and the second conducting metal 320 may be same.

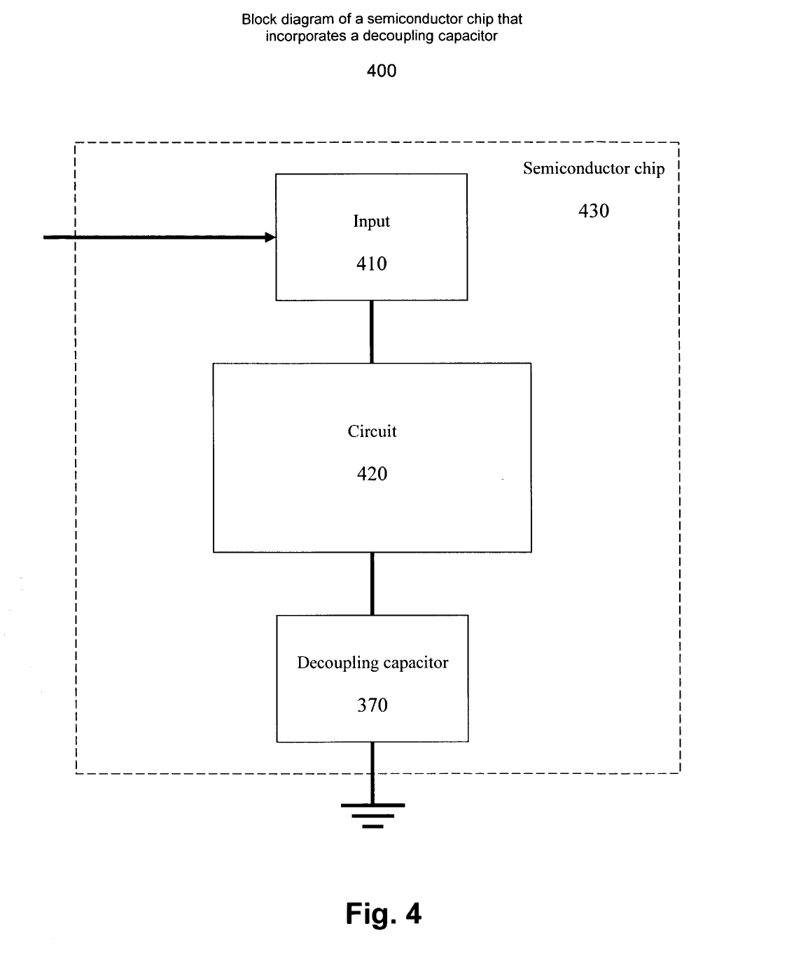

A first interlayer dielectric 210 may be utilized between the first conducting metal 220 and a ground. A second interlayer dielectric 310 may be used between the decoupling capacitor 370 and a surface of the semiconductor chip 430 (see FIG. 4). The first interlayer dielectric 210 between the first conducting metal 220 and ground need not be the same as the second interlayer dielectric 310 between the decoupling capacitor 370 and the surface of the semiconductor chip 430. However, the first interlayer dielectric 210 and the second interlayer dielectric 310 may be the same. A fourth conducting metal 340 and a fifth conducting metal 350 may connect the protective layer 230 to the surface of the semiconductor chip 430. The first conducting metal 220 and a sixth conducting metal 360 may connect the protective layer 230 to ground. A second conducting metal 320 and a third conducting metal 330 may connect the barrier metal 250 to the surface of the semiconductor chip 430. None of the first conducting metal 220, the second conducting metal 320, the third conducting metal 330, the fourth conducting metal 340, the fifth conducting metal 350, nor the sixth conducting metal need be composed of the same material. However, any of the first conducting metal 220, the second conducting metal 320, the third conducting metal 330, the fourth conducting metal 340, the fifth conducting metal 350, and the sixth conducting metal 360 may be composed of the same material.

FIG. 4 illustrates a block diagram of a semiconductor chip that incorporates a decoupling capacitor according to an embodiment of the present invention. The semiconductor chip 430 includes an input 410, a circuit 420, and a decoupling capacitor 370. The input 410 receives a signal. The circuit 420 manipulates the signal. The decoupling capacitor 370 is electrically coupled between the circuit 420 and ground. “Electrically coupled between the circuit and ground” is defined to include a situation in which the decoupling capacitor 370 is electrically coupled between a power input of the circuit 420 and ground. For example, DC power may be transmitted through a metalization layer to the power input of the circuit 420, and the decoupling capacitor 370 may be electrically coupled between the metalization layer and the ground.

According to an embodiment of the present invention, the semiconductor chip 430 may be a microprocessor chip. In another embodiment, the semiconductor chip 430 may be a digital signal processor chip, but in general, the present decoupling capacitor is useful in all types of semiconductor devices.

FIG. 5 illustrates a block diagram of an electrical signal processing system according to an embodiment of the present invention. The electrical signal processing system 500 includes a semiconductor chip 430 and a circuit board 510. The circuit board 510 is connected to the semiconductor chip 430.

According to an embodiment of the present invention, the circuit board 510 may be a motherboard. In another embodiment, the circuit board 510 may be a sound card. In yet another embodiment, the circuit board 510 may be a video card.

The method of fabricating a decoupling capacitor 100 according to an embodiment of the present invention provides a simpler and more manufacturable method to fabricate a decoupling capacitor 370 than traditional methods. For example, a portion of a photoresist 260 may be removed 170 by an oxygen plasma ash operation without requiring additional operations to ensure that a first conducting metal 220 is not exposed during the oxygen plasma ash operation. The portion of the photoresist 260 may be removed in this manner because in an embodiment of the present invention, a protective layer 230 protects the conducting metal 200 against exposure. Furthermore, selectively depositing 110 the protective layer 230 on the first conducting metal 220 may eliminate a need for a silicon nitride (“SiN”) etch stop or a silicon carbide (“SiC”) etch stop, thereby allowing for a wider tolerance for non-uniformity. This scheme may also reduce the likelihood of shortening a bottom electrode of a decoupling capacitor 370 due to an incomplete etch. In addition, a dielectric 240 may improve electromigration performance.

While the description above refers to particular embodiments of the present invention, it will be understood that many modifications may be made without departing from the spirit thereof. The accompanying claims are intended to cover such modifications as would fall within the true scope and spirit of an embodiment of the present invention. The presently disclosed embodiments are therefore to be considered in all respects as illustrative and not restrictive, the scope of an embodiment of the invention being indicated by the appended claims, rather than the foregoing description, and all changes that come within the meaning and range of equivalency of the claims are therefore intended to be embraced therein.

What is claimed is:

1. A method of fabricating a decoupling capacitor, comprising:
selectively depositing a protective layer on a first conducting metal, wherein the protective layer acts as a first electrode of the decoupling capacitor;
depositing a dielectric on the protective layer;
depositing a barrier metal on the dielectric, wherein the barrier metal acts as a second electrode of the decoupling capacitor;
defining an approximate shape of the decoupling capacitor by utilizing a mask;
exposing a photoresist to ultraviolet light, wherein the photoresist is applied on the barrier metal;
etching a portion of the barrier metal; and
removing a quantity of the photoresist.

2. The method according to claim 1, wherein the protective layer includes cobalt.

3. The method according to claim 1, wherein the protective layer includes tungsten.

4. The method according to claim 1, wherein the first conducting metal includes copper.

5. The method according to claim 1, wherein the barrier metal includes tantalum.

6. The method according to claim 1, wherein the barrier metal includes titanium.

7. The method according to claim 1, wherein removing the quantity of the photoresist is performed by an oxygen plasma ash operation.

8. The method according to claim 1, wherein the dielectric has a high dielectric constant.

9. An article, comprising:
a storage medium having stored thereon instructions that when executed by a machine result in the following:
selectively depositing a protective layer on a first conducting metal, wherein the protective layer acts as a first electrode of a decoupling capacitor;
depositing a dielectric on the protective layer;
depositing a barrier metal on the dielectric, wherein the barrier metal acts as a second electrode of the decoupling capacitor;
exposing a photoresist to ultraviolet light, wherein the photoresist is applied on the barrier metal;
defining an approximate shape of the decoupling capacitor by utilizing a mask;
etching a portion of the barrier metal; and
removing a quantity of the photoresist.

10. The article according to claim 9, wherein the protective layer includes cobalt.

11. The article according to claim 9, wherein the protective layer includes tungsten.

12. The article according to claim 9, wherein the first conducting metal includes copper.

13. The article according to claim 9, wherein the barrier metal includes tantalum.

14. The article according to claim 9, wherein the barrier metal includes titanium.

15. The article according to claim 9, wherein removing the quantity of the photoresist is performed by an oxygen plasma ash operation.

16. The article according to claim 9, wherein the dielectric has a high dielectric constant.

17. A decoupling capacitor, comprising:
a protective layer to act as a first electrode of the decoupling capacitor, wherein the protective layer is selectively deposited on a first conducting metal, and the protective layer being selected from the group of:
cobalt and tungsten;
a dielectric connected to the protective layer; and
a barrier metal connected to the dielectric and to a second conducting metal, wherein the barrier metal acts as a second electrode of the decoupling capacitor.

18. The decoupling capacitor according to claim 17, wherein the protective layer further acts as an oxygen barrier to the first conducting metal.

19. The decoupling capacitor according to claim 17, wherein the protective layer further acts as a diffusion barrier of the first conducting metal to the dielectric.

20. The decoupling capacitor according to claim 17, wherein the barrier metal includes tantalum.

21. The decoupling capacitor according to claim 17, wherein the barrier metal includes titanium.

22. A decoupling capacitor, wherein the decoupling capacitor is formed by
selectively depositing a protective layer on a first conducting metal, wherein the protective layer acts as a first electrode of the decoupling capacitor,
depositing a dielectric on the protective layer,
depositing a barrier metal on the dielectric, wherein the barrier metal acts as a second electrode of the decoupling capacitor,
utilizing a mask to define an approximate shape of the decoupling capacitor,
exposing a photoresist to ultraviolet light, wherein the photoresist is applied on the barrier metal,
etching a portion of the barrier metal, and
removing a quantity of the photoresist.

23. The decoupling capacitor according to claim 22, wherein the protective layer includes cobalt.

24. The decoupling capacitor according to claim 22, wherein the protective layer includes tungsten.

25. A semiconductor chip, comprising:
an input to receive a signal;
a circuit to manipulate the signal; and
a decoupling capacitor electrically coupled between the circuit and a ground, wherein the decoupling capacitor includes
a protective layer to act as a first electrode of the decoupling capacitor, wherein the protective layer is selectively deposited on a first conducting metal, and the protective layer being selected from the group of:
cobalt and tungsten,
a dielectric connected to the protective layer, and
a barrier metal connected to the dielectric and to a second conducting metal, wherein the barrier metal acts as a second electrode of the decoupling capacitor.

26. The semiconductor chip according to claim 25, wherein the semiconductor chip is a microprocessor chip.

27. The semiconductor chip according to claim 25, wherein the semiconductor chip is a digital signal processor chip.

28. The semiconductor chip according to claim 25, wherein the barrier metal includes tantalum.

29. The semiconductor chip according to claim 25, wherein the barrier metal includes titanium.

30. A semiconductor chip, comprising:
an input to receive a signal;
a circuit to manipulate the signal; and
a decoupling capacitor electrically coupled between the circuit and a ground, wherein the decoupling capacitor is formed by
selectively depositing a protective layer on a first conducting metal, wherein the protective layer acts as a first electrode of the decoupling capacitor,
depositing a dielectric on the protective layer,
depositing a barrier metal on the dielectric, wherein the barrier metal acts as a second electrode of the decoupling capacitor,
utilizing a mask to define an approximate shape of the decoupling capacitor,
exposing a photoresist to ultraviolet light, wherein the photoresist is applied on the barrier metal,
etching a portion of the barrier metal, and
removing a quantity of the photoresist.

31. The semiconductor chip according to claim 30, wherein the protective layer includes cobalt.

32. The semiconductor chip according to claim 30, wherein the protective layer includes tungsten.

33. The semiconductor chip according to claim 30, wherein the semiconductor chip is a microprocessor chip.

34. The semiconductor chip according to claim 30, wherein the semiconductor chip is a digital signal processor chip.
